(19) United States
(12) Patent Application Publication
(10) Pub. No.: US 2020/0295179 A1
(43) Pub. Date: Sep. 17, 2020

(54) SEMICONDUCTOR DEVICE

(71) Applicant: SHINDENGEN ELECTRIC MANUFACTURING CO., LTD., Chiyoda-ku, Tokyo (JP)

(72) Inventors: Masato KISHI, Saitama (JP); Toshiyuki TAKEMORI, Saitama (JP); Toshitaka AKIMOTO, Saitama (JP); Gotaro TAKEMOTO, Saitama (JP); Eiki ITO, Saitama (JP)

(21) Appl. No.: 15/775,442

(22) PCT Filed: Jan. 14, 2016
(86) PCT No.: PCT/JP2016/050957

§ 371 Date: May 11, 2018

(51) Int. Cl. H01L 29/78; H01L 29/40

(52) U.S. Cl. CPC H01L 29/7813; H01L 29/407

(57) ABSTRACT

A semiconductor device includes: a gate electrode disposed in the inside of a trench via a gate insulating film; a shield electrode positioned between the gate electrode and a bottom of the trench; an electric insulating region expanding between the gate electrode and the shield electrode, and further expanding along a side wall and the bottom of the trench so as to separate the shield electrode from the side wall and the bottom; a source electrode electrically connected to an n⁺-type source region, and electrically connected to the shield electrode on both end portions of the trench as viewed in a plan view, wherein the shield electrode has high resistance regions positioned at both end portions of the trench as viewed in a plan view, and a low resistance region positioned at a position sandwiched by the high resistance regions.

### RELATED APPLICATIONS

The present application is a National Phase of International Application Number PCT/JP2016/050957, filed Jan. 14, 2016.

### TECHNICAL FIELD

The present invention relates to a semiconductor device.

### BACKGROUND ART

Conventionally, there has been known a semiconductor device having a so-called shield gate structure (see patent literature 1, for example). As shown in FIG. 23A, a conventional semiconductor device 900 includes: a semiconductor base body 910 having an n⁺-type drain region 912, an n⁻-type drift region 914, a p-type base region 916 and an n⁺-type source region 918; a trench 922 formed in the inside of the semiconductor base body 910, having a bottom disposed adjacently to the n⁻-type drift region 914 and a side wall disposed adjacently to the p-type base region 916 and the n⁻-type drift region 914, and formed into a stripe pattern as viewed in a plan view; a gate electrode 926 disposed in the inside of the trench 922 and opposedly facing the p-type base region 916 with a gate insulating film 924 interposed therebetween on a portion of the side wall; a shield electrode 930 disposed in the inside of the trench 922 and positioned between the gate electrode 926 and the bottom of the trench 922; an electric insulating region 928 disposed in the inside of the trench 922, the electric insulating region 928 expanding between the gate electrode 926 and the shield electrode 930, and further expanding along the side wall and the bottom of the trench 922 so as to separate the shield electrode 930 from the side wall and the bottom; a source electrode 934 formed above the semiconductor base body 910 and electrically connected to the n⁺-type source region 918 and the shield electrode 930; and a drain electrode 936 formed adjacently to the n⁺-type drain region 912.

The conventional semiconductor device 900 includes the shield electrode 930 disposed in the inside of the trench 922 and positioned between the gate electrode 926 and the bottom of the trench 922. Accordingly, a distance from the gate electrode 926 to the bottom of the trench 922 becomes long and hence, a gate-drain capacitance C_{GD} (see FIG. 23B) is lowered. As a result, a gate charge current amount and a gate discharge current amount are lowered and hence, a switching speed can be increased. Further, a distance between a corner portion of the trench 922 where the concentration in an electric field is liable to occur and the gate electrode 926 can be increased. Still further, an electric field can be attenuated in the electric insulating region 928 and hence, a withstand voltage can be increased.

### CITATION LIST

### Patent Literature

PTL 1: Japanese Patent No. 4790908

### SUMMARY OF INVENTION

### Technical Problem

However, from studies which the inventors of the present invention have made, it has been found that, in the conventional semiconductor device 900, there arises a case where ringing occurs or a high surge voltage is generated at the time of turning off a switch. Accordingly, the inventors of the present invention have considered the use of a high resistance shield electrode (for example, a shield electrode having higher resistance than the source electrode or the gate electrode) as the shield electrode (see FIG. 3 and FIG. 4A). With such a configuration, due to high internal resistance in the shield electrode, a change in potential of the drain electrode can be attenuated at the time of turning off a switch and hence, ringing which occurs at the time of turning off a switch can be suppressed, and a surge voltage which occurs at the time of turning off a switch can be reduced (see FIG. 4B).

However, when the high resistance shield electrode is used as the shield electrode as described above, in the latter half of a switching period, a difference in potential is generated along a line of the shield electrode and hence, a gate voltage V_{GS} rises through a gate-source capacitance C_{GS} thus giving rise to a drawback that an erroneous operation (self turn-on) is liable to occur (see symbol A in FIG. 4B). Further, a switching speed becomes slow (see FIG. 4B) thus giving rise to a drawback that a switching loss is increased.

On the other hand, when a low resistance shield electrode is used as the shield electrode (see FIG. 5 and FIG. 6A), a change in potential of the drain electrode cannot be attenuated at the time of turning off a switch and hence, it is difficult to acquire an advantageous effect that ringing is suppressed, and a surge voltage is lowered (see FIG. 6B).

The present invention has been made to overcome such drawbacks, and it is an object of the present invention to provide a semiconductor device which can suppress ringing which occurs at the time of turning off a switch, and can lower a surge voltage at the time of turning off a switch. The semiconductor device can also suppress an erroneous operation (self turn-on) which occurs due to rising of a gate voltage V_{GS} at the time of turning off a switch and, at the same time, the semiconductor device can reduce a drawback that a switching loss is increased.

### Solution to Problem

[1] According to one aspect of the present invention, there is provided a semiconductor device which includes:

a semiconductor base body having a drain region of a first-conductive-type, a drift region of the first-conductive-type disposed adjacently to the drain region, a base region of a second-conductive-type disposed adjacently to the drift region, and a source region of the first-conductive-type disposed adjacently to the base region;

a trench formed in the inside of the semiconductor base body, having a bottom disposed adjacently to the drift region and a side wall disposed adjacently to the base region and the drift region, and formed into a stripe pattern as viewed in a plan view;

a gate electrode disposed in the inside of the trench and opposedly facing the base region with a gate insulating film interposed therebetween on a portion of the side wall;

a shield electrode disposed in the inside of the trench and positioned between the gate electrode and the bottom of the trench;

an electric insulating region disposed in the inside of the trench, the electric insulating region expanding between the gate electrode and the shield electrode, and further expanding along the side wall and the bottom of the trench so as to separate the shield electrode from the side wall and the bottom;

a source electrode formed above the semiconductor base body, electrically connected to the source region, and electrically connected to the shield electrode on at least one of both end portions of the trench as viewed in a plan view; and

a drain electrode formed adjacently to the drain region, wherein

the shield electrode has a high resistance region positioned at an end portion of the trench which is electrically connected to the source electrode out of both end portions of the trench as viewed in a plan view, and a low resistance region positioned at a position in front of the high resistance region as viewed from the source electrode.

The above-mentioned high resistance region can be also referred to as a first region positioned at both end portions of the trench as viewed in a plan view and having a first resistance, and the above-mentioned low resistance region can be also referred to as a second region positioned at a position sandwiched by the first regions and having a second resistance lower than the first resistance.

[2] In the semiconductor device of the present invention, it is preferable that both the high resistance region and the low resistance region be made of a same semiconductor material containing a dopant, and dopant concentration in the low resistance region be higher than dopant concentration in the high resistance region.

[3] In the semiconductor device of the present invention, it is preferable that the high resistance region and the low resistance region be made of different materials respectively, and electric resistivity of a material for forming the low resistance region be lower than electric resistivity of a material for forming the high resistance region.

[4] In the semiconductor device of the present invention, it is preferable that both the high resistance region and the low resistance region be made of a same material, and a cross-sectional area of the high resistance region taken along a plane orthogonal to a longitudinal direction of the trench be smaller than a cross-sectional area of the low resistance region taken along a plane orthogonal to a longitudinal direction of the trench.

[5] In the semiconductor device of the present invention, it is preferable that both the high resistance region and the low resistance region be made of a same semiconductor material containing a dopant, and the low resistance region has a high concentration dopant region containing a dopant having higher concentration than a dopant in the high resistance region and extending along a longitudinal direction of the trench.

[6] In the semiconductor device of the present invention, it is preferable that both the high resistance region and the low resistance region have a high concentration dopant region made of a same semiconductor material containing a dopant and extending along a longitudinal direction of the trench, and a cross-sectional area of the high concentration dopant region in the high resistance region taken along a plane orthogonal to a longitudinal direction of the trench be smaller than a cross-sectional area of the high concentration dopant region in the low resistance region taken along a plane orthogonal to a longitudinal direction of the trench.

[7] In the semiconductor device of the present invention, it is preferable that in the shield electrode, the shield electrode extending adjacently to a side of a chip as viewed in a plan view be wholly formed of the high resistance region.

[8] In the semiconductor device of the present invention, it is preferable that in the shield electrode, the shield electrode extending adjacently to a side of a gate pad as viewed in a plan view be configured such that a portion of the shield electrode extending adjacently to the side of the gate pad as viewed in a plan view is formed of the high resistance region.

[9] In the semiconductor device of the present invention, it is preferable that a contact structure for electrically connecting the shield electrode and the source electrode be formed on an end portion of the shield electrode connected to the source electrode out of both end portions of the shield electrode.

[10] In the semiconductor device of the present invention, it is preferable that the contact structure be formed in a second low resistance region having a lower resistance than the high resistance region.

[11] In the semiconductor device of the present invention, it is preferable that the source electrode be electrically connected to the shield electrode on both end portions of the trench as viewed in a plan view, the high resistance region be positioned on both end portions of the trench as viewed in a plan view, and the low resistance region be positioned at a position sandwiched by the high resistance regions.

### Advantageous Effects of Invention

According to the semiconductor device of the present invention, the semiconductor device includes the shield electrode having the high resistance region positioned at the end portion of the trench electrically connected to the source electrode out of both end portions of the trench, and the low resistance region positioned at the position in front of the high resistance region as viewed from the source electrode, as the shield electrode (see FIG. 1, FIG. 2A and FIG. 2B). With such a configuration, due to the presence of the high resistance region, a drain-source resistance can be increased. Accordingly, a change in potential of the drain electrode at the time of turning off a switch can be attenuated and hence, ringing which occurs at the time of turning off a switch can be suppressed (and a surge voltage can be lowered) thus suppressing the generation of an erroneous operation (see FIG. 2C).

Due to the presence of the low resistance region, a difference in potential of the shield electrode generated along a line of the shield electrode can be lowered whereby it is possible to suppress the occurrence of a phenomenon that V_{GS} rises in the latter half of a switching period resulting in an erroneous operation (see symbol A in FIG. 2C). Further, due to the presence of the low resistance region, a switching speed can be increased (see FIG. 2C) and hence, the increase of a switching loss can be prevented.

Further, due to the presence of the high resistance region positioned on the end portion of the trench electrically connected to the source electrode out of both end portions of the trench, a potential generated in the shield electrode is increased and hence, the extension of a depletion layer in the drift region via Cds can be suppressed. At this stage of the operation, a switching operation of the MOSFET is gradually shifted from the end portion of the trench electrically connected to the source electrode out of both end portions of the trench to the center of the trench. Accordingly, the extension of the depletion layer at the end portion of the trench electrically connected to the source electrode out of both end portions of the trench can be suppressed, leading to the reduction of an adverse effect caused by a surge voltage from the outside.

### BRIEF DESCRIPTION OF DRAWINGS

FIG. 1 is a plan view for describing a semiconductor device 100 according to an embodiment 1.

FIG. 2A to FIG. 2C are views for describing the semiconductor device 100 according to the embodiment 1, wherein FIG. 2A is a cross-sectional view of a main part (a region including a high resistance region 130a) of the semiconductor device 100, FIG. 2B is a cross-sectional view of a main part (a region including a low resistance region 130b) of the semiconductor device 100, and FIG. 2C is a view showing a response waveform at the time of turning off a switch of the semiconductor device 100.

FIG. 3 is a plan view for describing a semiconductor device 100a according to a comparison example 1.

FIG. 4A and FIG. 4B are views for describing the semiconductor device 100a according to the comparison example 1, wherein FIG. 4A is a cross-sectional view of a main part of the semiconductor device 100a, and FIG. 4B is a view showing a response waveform at the time of turning off a switch of the semiconductor device 100a.

FIG. 5 is a plan view for describing a semiconductor device 100b according to a comparison example 2.

FIG. 6A and FIG. 6B are views for describing the semiconductor device 100b according to the comparison example 2, wherein FIG. 6A is a cross-sectional view of a main part of the semiconductor device 100b, and FIG. 6B is a view showing a response waveform at the time of turning off a switch of the semiconductor device 100b.

FIG. 7A to FIG. 7C are views for describing a manner of operation and an advantageous effect acquired by the semiconductor device 100 according to the embodiment 1, wherein FIG. 7A is a view where parasitic resistances and parasitic capacitances are additionally described in a cross-sectional view of the main part (the region including the high resistance region 130a) of the semiconductor device 100, FIG. 7B is a view where parasitic resistances and parasitic capacitances are additionally described in a cross-sectional view of the main part (the region including the low resistance region 130b) of the semiconductor device 100, and FIG. 7C is an equivalent circuit diagram of the semiconductor device 100.

FIG. 8A to FIG. 8D are views for describing a method of manufacturing the semiconductor device 100 according to the embodiment 1, wherein FIG. 8A to FIG. 8D are views showing respective steps.

FIG. 9A to FIG. 9D are views for describing the method of manufacturing the semiconductor device 100 according to the embodiment 1, wherein FIG. 9A to FIG. 9D are views showing respective steps.

FIG. 10A to FIG. 10D are views for describing the method of manufacturing the semiconductor device 100 according to the embodiment 1, wherein FIG. 10A to FIG. 10D are views showing respective steps.

FIG. 11A to FIG. 11D are views for describing the method of manufacturing the semiconductor device 100 according to the embodiment 1, wherein FIG. 11A to FIG. 11D are views showing respective steps.

In FIG. 8A to FIG. 11D and FIG. 15A to FIG. 15D, FIG. 18A to FIG. 18D and FIG. 19A to FIG. 19D described later, drawings on a left-side row are step views as viewed from a cross section of a main part (a region including a high resistance region 130a) of the semiconductor device, and drawings on a right-side row are step views as viewed from a cross section of a main part (a region including a low resistance region 130b) of the semiconductor device.

FIG. 12A and FIG. 12B are cross-sectional views of main parts of a semiconductor device according to an embodiment 2, wherein FIG. 12A is a cross-sectional view of a main part (a region including a high resistance region 130a) of the semiconductor device, and FIG. 12B is a cross-sectional view of a main part (a region including a low resistance region 130b) of the semiconductor device.

FIG. 13A and FIG. 13B are cross-sectional views of main parts of a semiconductor device 102 according to an embodiment 3, wherein FIG. 13A is a cross-sectional view of a main part (a region including a high resistance region 130a) of the semiconductor device 102, and FIG. 13B is a cross-sectional view of a main part (a region including a low resistance region 130b) of the semiconductor device 102.

FIG. 14 is a plan view for describing the semiconductor device 102 according to the embodiment 3.

FIG. 15A to FIG. 15D are views for describing a method of manufacturing the semiconductor device 102 according to the embodiment 3, wherein FIG. 15A to FIG. 15D are views showing respective steps. Steps substantially equal to the steps shown in FIG. 8A to FIG. 11D are omitted in FIG. 15A to FIG. 15D.

FIG. 16A and FIG. 16B are cross-sectional views of main parts of a semiconductor device according to an embodiment 4, wherein FIG. 16A is a cross-sectional view of a main part (a region including a high resistance region 130a) of the semiconductor device, and FIG. 16B is a cross-sectional view of a main part (a region including a low resistance region 130b) of the semiconductor device.

FIG. 17A and FIG. 17B are cross-sectional views of main parts of a semiconductor device according to an embodiment 5, wherein FIG. 17A is a cross-sectional view of a main part (a region including a high resistance region 130a) of the semiconductor device, and FIG. 17B is a cross-sectional view of a main part (a region including a low resistance region 130b) of the semiconductor device.

FIG. 18A to FIG. 18D are views for describing a method of manufacturing the semiconductor device according to the embodiment 4, wherein FIG. 18A to FIG. 18D are views showing respective steps. Steps substantially equal to the steps shown in FIG. 8A to FIG. 11D are omitted in FIG. 18A to FIG. 18D.

FIG. 19A to FIG. 19D are views for describing a method of manufacturing the semiconductor device according to the embodiment 5, wherein FIG. 19A to FIG. 19D are views showing respective steps. Steps substantially equal to the steps shown in FIG. 8A to FIG. 11D are omitted in FIG. 19A to FIG. 19D.

FIG. 20A to FIG. 20J are plan views for describing an end portion of a shield electrode, wherein FIG. 20A is a plan view showing an end portion of a shield electrode 130 in the semiconductor device 100 according to the embodiment 1, FIG. 20B is a plan view of an end portion of a shield electrode 130 in the semiconductor device according to the embodiment 2, FIG. 20C is a plan view of an end portion of a shield electrode 130 in the semiconductor device 102 according to the embodiment 3, FIG. 20D is a plan view of an end portion of a shield electrode 130 in the semiconductor device according to the embodiment 4, and FIG. 20E is a plan view of an end portion of a shield electrode 130 in the semiconductor device 100 according to the embodiment 5. FIG. 20F is a plan view showing an end portion of a shield electrode 130 in a modification of the semiconductor device 100 according to the embodiment 1, FIG. 20G is a plan view showing an end portion of a shield electrode 130 in a modification of the semiconductor device according to the embodiment 2, FIG. 20H is a plan view showing an end portion of a shield electrode 130 in a modification of the semiconductor device 102 according to the embodiment 3, FIG. 201 is a plan view showing an end portion of a shield electrode 130 in a modification of the semiconductor device according to the embodiment 4, and FIG. 20J is a plan view showing an end portion of a shield electrode 130 in a modification of the semiconductor device 100 according to the embodiment 5.

FIG. 21 is a plan view for describing a semiconductor device 105 according to an embodiment 6.

FIG. 22 is a plan view for describing a semiconductor device 106 according to an embodiment 7.

FIG. 23A and FIG. 23B are views for describing a conventional semiconductor device 900, wherein FIG. 23A is a view where parasitic resistances and parasitic capacitances are additionally described in a cross-sectional view of the semiconductor device 900, and FIG. 23B is an equivalent circuit diagram of the semiconductor device 900.

### DESCRIPTION OF EMBODIMENTS

Hereinafter, a semiconductor device according to the present invention is described in conjunction with embodiments shown in the drawings.

### Embodiment 1

### 1. Semiconductor Device

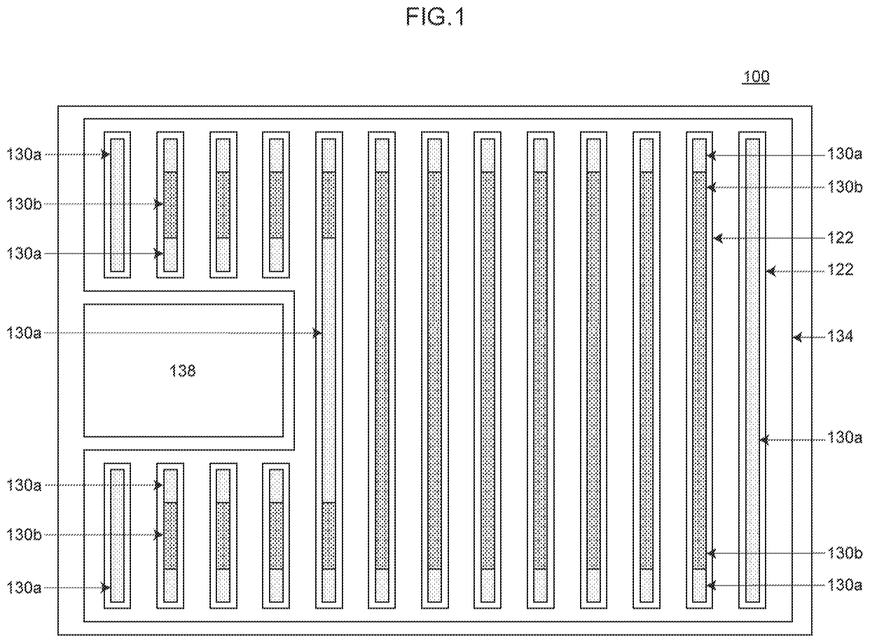

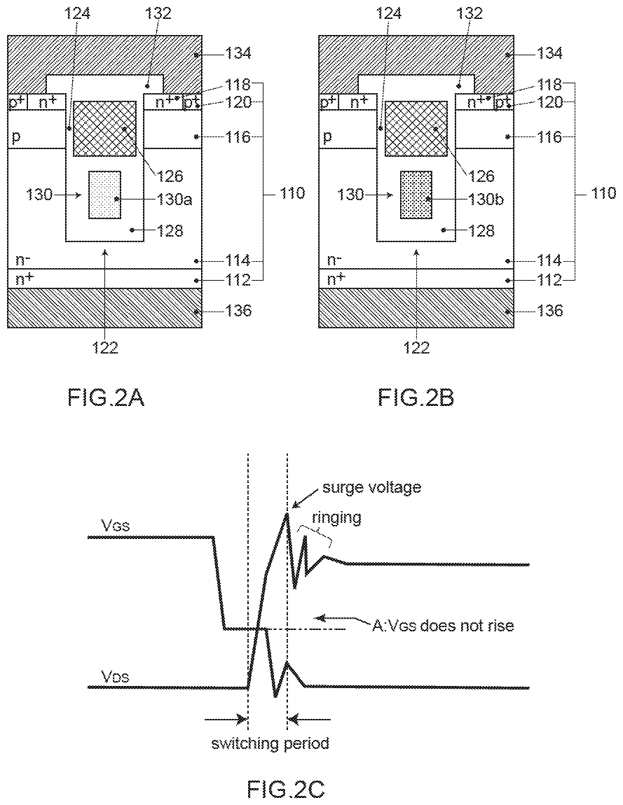

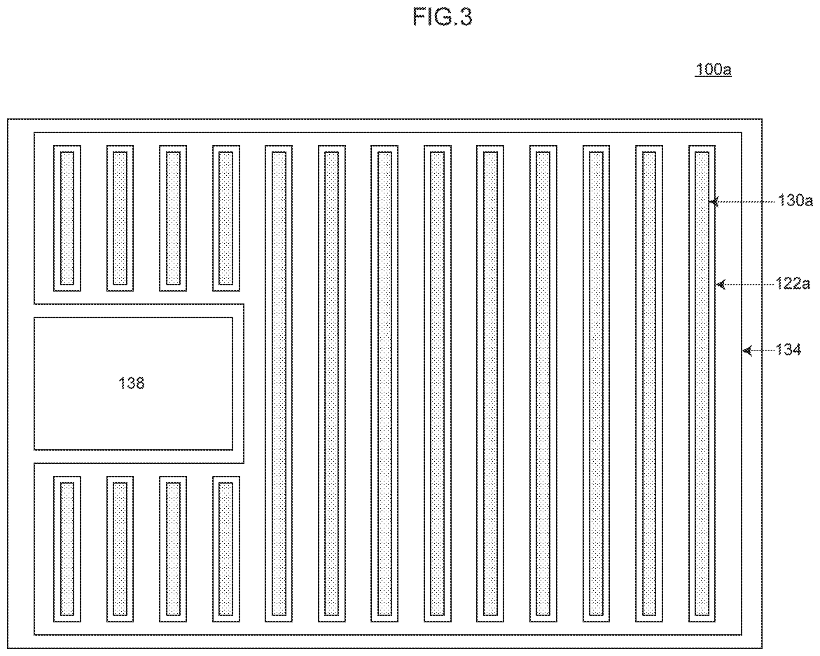

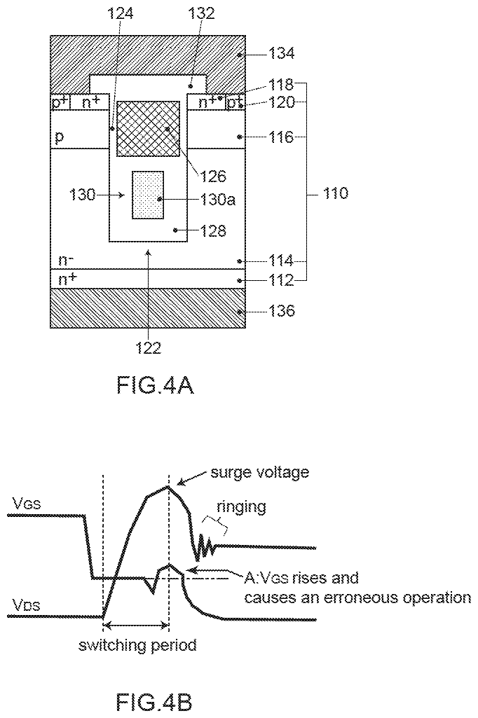

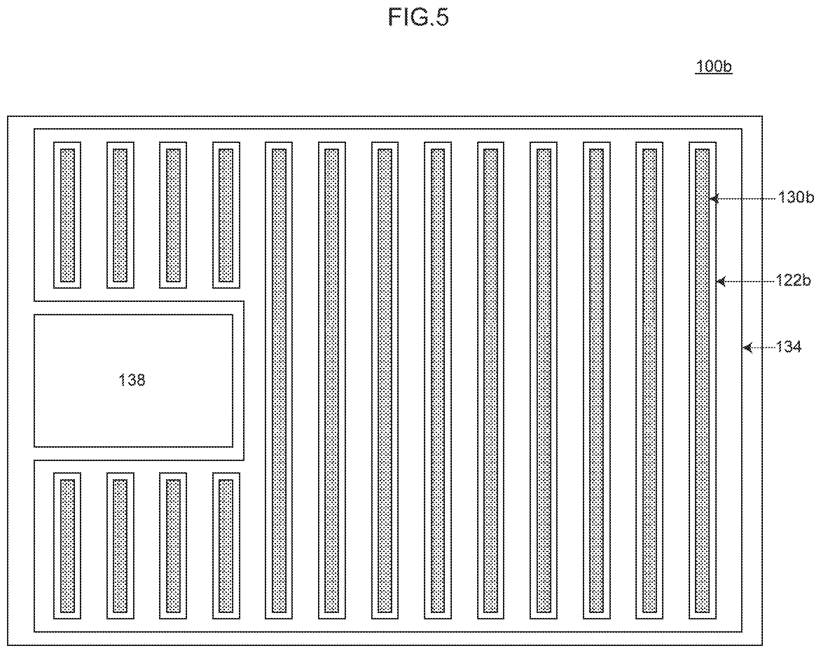

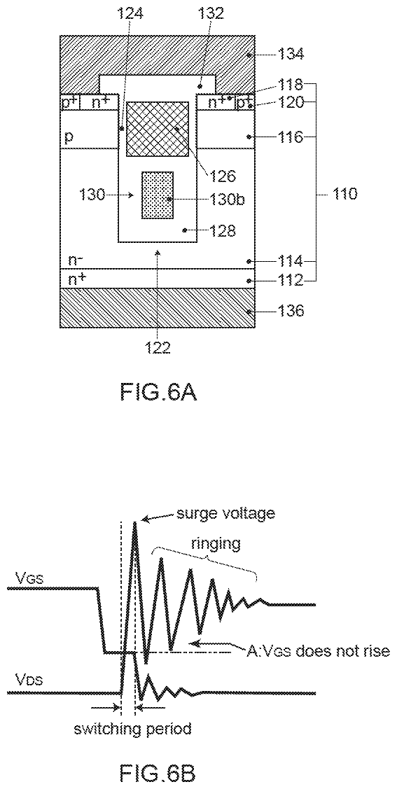

As shown in FIG. 1, FIG. 2A and FIG. 2B, a semiconductor device 100 according to an embodiment 1 includes: a semiconductor base body 110 having an n⁺-type drain region (a drain region of a first-conductive-type) 112, an n⁻-type drift region (a drift region of the first-conductive-type) 114 disposed adjacently to the n⁺-type drain region 112, a p-type base region (a base region of a second-conductive-type) 116 disposed adjacently to the n⁻-type drift region 114, and an n⁺-type source region (a source region of the first-conductive-type) 118 disposed adjacently to the p-type base region 116; a trench 122 formed in the inside of the semiconductor base body 110, having a bottom disposed adjacently to the n⁻-type drift region 114 and a side wall disposed adjacently to the p-type base region 116 and the n⁻-type drift region 114, and formed into a stripe pattern as viewed in a plan view; a gate electrode 126 disposed in the inside of the trench 122 and opposedly facing the p-type base region 116 with a gate insulating film 124 interposed therebetween on a portion of the side wall; a shield electrode 130 disposed in the inside of the trench 122 and positioned between the gate electrode 126 and the bottom of the trench 122; an electric insulating region 128 disposed in the inside of the trench 122, the electric insulating region 128 expanding between the gate electrode 126 and the shield electrode 130, and further expanding along the side wall and the bottom of the trench 122 so as to separate the shield electrode 130 from the side wall and the bottom; a source electrode 134 formed above the semiconductor base body 110, electrically connected to the n⁺-type source region 118, and electrically connected to the shield electrode 130 on both end portions of the trench 122 as viewed in a plan view; and a drain electrode 136 formed adjacently to the n⁺-type drain region 112. In FIG. 2A and FIG. 2B, symbol 132 indicates an interlayer insulating film 132.

The semiconductor device 100 according to the embodiment 1 is a power MOSFET.

In the semiconductor device 100 according to the embodiment 1, the shield electrode 130 has high resistance regions 130a positioned at both end portions of the trench 122 as viewed in a plan view, and a low resistance region 130b positioned at a position sandwiched by the high resistance regions 130a. Both the high resistance regions 130a and the low resistance region 130b are made of the same semiconductor material containing a dopant, and dopant concentration in the low resistance region 130b is higher than dopant concentration in the high resistance region 130a.

In the semiconductor device 100 according to the embodiment 1, in the shield electrode 130, the shield electrode extending adjacently to a side of a chip as viewed in a plan view is wholly formed of the high resistance region 130a. In the shield electrode 130, the shield electrode extending adjacently to a side of a gate pad 138 as viewed in a plan view is configured such that a portion of the shield electrode extending adjacently to the side of the gate pad 138 as viewed in a plan view is formed of the high resistance region 130a.

A thickness of the n⁺-type drain region 112 is set to a value which falls within a range of from 50 μm to 500 μm (for example, 350 μm), and dopant concentration in the n⁺-type drain region 112 is set to 1×10¹⁸cm⁻³ to 1×10²⁰cm⁻³ (for example, 1×10¹⁹cm⁻³). A thickness of the n⁻-type drift region 114 is set to a value which falls within a range of from 10 μm to 50 μm (for example, 15 μm), and dopant concentration in the n⁻-type drift region 114 is set to 1×10¹⁴cm⁻³ to 1×10¹⁷cm⁻³ (for example, 1×10¹⁵cm⁻³). A thickness of the p-type base region 116 is set to a value which falls within a range of from 2 μm to 10 μm (for example, 5 μm), and dopant concentration in the p-type base region 116 is set to 1×10¹⁶cm⁻³ to 1×10¹⁸cm⁻³ (for example, 1×10¹⁷cm⁻³).

A depth of the trench 122 is set to a value which falls within a range of from 4 μm to 20 μm (for example, 12 μm), and a pitch of the trench 122 is set to a value which falls within a range of from 3 μm to 15 μm (for example, 10 μm).

The gate insulating film 124 is formed of a silicon dioxide film formed by a thermal oxidation method, for example, and a thickness of the gate insulating film 124 is set to a value which falls within a range of from 20 nm to 200 nm (for example, 100 nm).

The gate electrode 126 is formed of a low resistance polysilicon formed by a CVD method, for example, and a thickness of the gate electrode 126 is set to a value which falls within a range of from 2 μm to 10 μm (for example, 5 μm).

The shield electrode 130 is, as described previously, disposed in the inside of the trench 122 and positioned between the gate electrode 126 and the bottom of the trench 122. The high resistance region 130a is made of a high resistance polysilicon formed by a CVD method, for example, and a thickness of the high resistance region 130a is set to a value which falls within a range of from 1 μm to 4 μm (for example, 3 μm). The low resistance region 130b is made of a low resistance polysilicon formed by a CVD method, for example, and a thickness of the low resistance region 130b is set to a value which falls within a range of from 1 μm to 4 μm (for example, 3 μm).

A distance between the shield electrode 130 and the gate electrode 126 is set to a value which falls within a range of from 1 μm to 3 μm (for example, 2 μm), a distance between the shield electrode 130 and the bottom of the trench 122 is set to a value which falls within a range of from 1 μm to 3 μm (for example, 2 μm), and a distance between the shield electrode 130 and the side wall of the trench 122 is set to a value which falls within a range of from 1 μm to 3 μm (for example, 2 μm).

A depth of the n⁺-type source region 118 is set to a value which falls within a range of from 1 μm to 3 μm (for example, 2 μm), and dopant concentration in the n⁺-type source region 118 is set to 1×10¹⁸cm⁻³ to 1×10²⁰cm⁻³ (for example, 2×10¹⁹cm⁻³).

A depth of a p⁺-type contact region 120 is set to a value which falls within a range of from 1 μm to 3 μm (for example, 2 μm), and dopant concentration in the p⁺-type contact region 120 is set to 1×10¹⁸cm⁻³ to 1×10²⁰cm⁻³ (for example, 2×10¹⁹cm⁻³).

An interlayer insulating film 132 is formed of a silicon dioxide film formed by a CVD method, for example, and a thickness of the interlayer insulating film 132 is set to a value which falls within a range of from 0.5 μm to 3 μm (for example, 1 μm).

The source electrode 134 is formed of an Al film or an Al alloy film (for example, an AlSi film), for example, and a thickness of the source electrode 134 is set to a value which falls within a range of from 1 μm to 10 μm (for example, 3 μm).

The drain electrode 136 is formed of a lamination film in which Ti, Ni, and Au are laminated in this order, and a thickness of the drain electrode 136 is set to a value which falls within a range of from 0.2 μm to 1.5 μm (for example, 1 μm).

In the semiconductor device 100 according to the embodiment 1, electric resistivity, dopant concentration and the like of the high resistance region 130a and the low resistance region 130b are not particularly limited. However, it is preferable that electric resistivity of the high resistance region 130a be 10 times or more as large as electric resistivity of the low resistance region 130b. It is more preferable that electric resistivity of the high resistance region 130a be 100 times or more as large as electric resistivity of the low resistance region 130b. Lengths (one-side lengths) of the high resistance region 130a and the low resistance region 130b along the longitudinal direction of the trench 122 are also not particularly limited. However, it is preferable that the length of the high resistance region 130a be 0.2 times or less as large as the length of the low resistance region 130b. It is more preferable that the length of the high resistance region 130a be 0.1 times or less as large as the length of the low resistance region 130b.

### 2. Advantageous Effects of Semiconductor Device

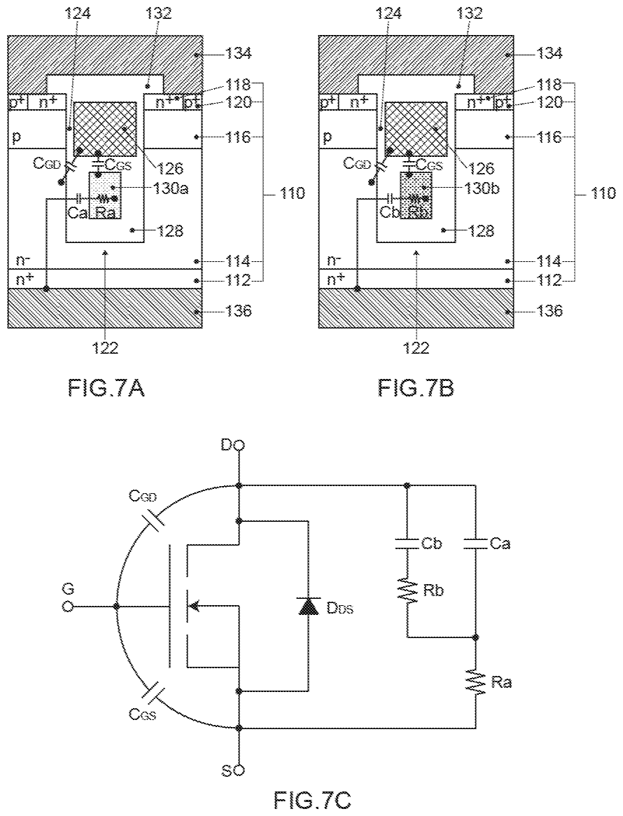

According to the semiconductor device 100 of the embodiment 1, the semiconductor device 100 includes the shield electrode 130 having the high resistance regions 130a positioned at both end portions of the trench and the low resistance region 130b positioned at the position sandwiched by the high resistance regions 130a, as the shield electrode 130 (see FIG. 1, FIG. 2A, and FIG. 2B) and hence, a resistance value of a resistance Ra in the high resistance region 130a (see FIG. 7) becomes higher than a resistance value of a resistance Rb in the low resistance region 130b (see FIG. 7). Due to the presence of the high resistance regions 130a, a drain-source resistance can be increased. Accordingly, a change in potential of the drain electrode 136 at the time of turning off a switch can be attenuated and hence, ringing which occurs at the time of turning off a switch can be suppressed (and a surge voltage can be lowered) thus suppressing the generation of an erroneous operation (see FIG. 2C).

Further, the resistance value of the resistance Rb in the low resistance region 130b (see FIG. 7) becomes lower than the resistance value of the resistance Ra in the high resistance region 130a (see FIG. 7). Due to the presence of the low resistance region 130b, a difference in potential generated along a line of the shield electrode 130 can be lowered and hence, it is possible to suppress an erroneous operation (self turn-on) which is generated due to rising of a V_{GS} in the latter half of a switching period (see symbol A in FIG. 2C). Further, due to the presence of the low resistance region 130b, a switching speed can be increased (see FIG. 2C) and hence, the increase of a switching loss can be prevented.

Due to the presence of the high resistance regions 130a positioned on both end portions of the trench 122, a potential generated in the shield electrode 130 is increased and hence, the extension of a depletion layer in the n⁻-type drift region 114 via Cds can be suppressed. At this stage of the operation, a switching operation of the MOSFET is gradually shifted from both end portions of the trench 122 to the center of the trench 122. Accordingly, the extension of the depletion layer at both end portions of the trench 122 can be suppressed, leading to the reduction of an adverse effect caused by a surge voltage from the outside.

According to the semiconductor device 100 according to the embodiment 1, in the shield electrode 130, the shield electrode 130 extending adjacently to the side of the chip as viewed in a plan view is wholly formed of the high resistance region 130a. With such a configuration, in the shield electrode, a potential generated in the shield electrode 130 becomes higher and hence, the extension of the depletion layer of the n⁻-type drift region 114 via Cds can be suppressed more effectively. Accordingly, an adverse effect caused by a surge voltage from the outside of the chip can be reduced.

According to the semiconductor device 100 of the embodiment 1, in the shield electrode 130, the shield electrode 130 extending adjacently to the side of the gate pad 138 as viewed in a plan view is configured such that a portion of the shield electrode 130 extending adjacently to the side of the gate pad 138 as viewed in a plan view is formed of the high resistance region 130a. With such a configuration, in the shield electrode, a potential generated in the shield electrode 130 becomes higher and hence, the extension of the depletion layer of the n⁻-type drift region 114 via Cds can be suppressed more effectively. Accordingly, an adverse effect caused by a surge voltage from the gate pad 138 can be reduced.

The semiconductor device 100 according to the embodiment 1 includes, as the shield electrode 130 thereof, a shield electrode in which both the high resistance regions 130a and the low resistance region 130b are made of the same semiconductor material containing a dopant, and dopant concentration in the low resistance region 130b is higher than dopant concentration in the high resistance region 130a. Accordingly, by setting a doping amount of a dopant to a suitable value, it is possible to relatively easily set electric resistivity of the high resistance region 130a and electric resistivity of the low resistance region 130b to desired values.

### 3. Method of Manufacturing Semiconductor Device

The semiconductor device 100 according to the embodiment 1 can be manufactured by a manufacturing method having the following manufacturing steps (method of manufacturing a semiconductor device according to the embodiment 1).

### (1) Semiconductor Base Body Preparing Step

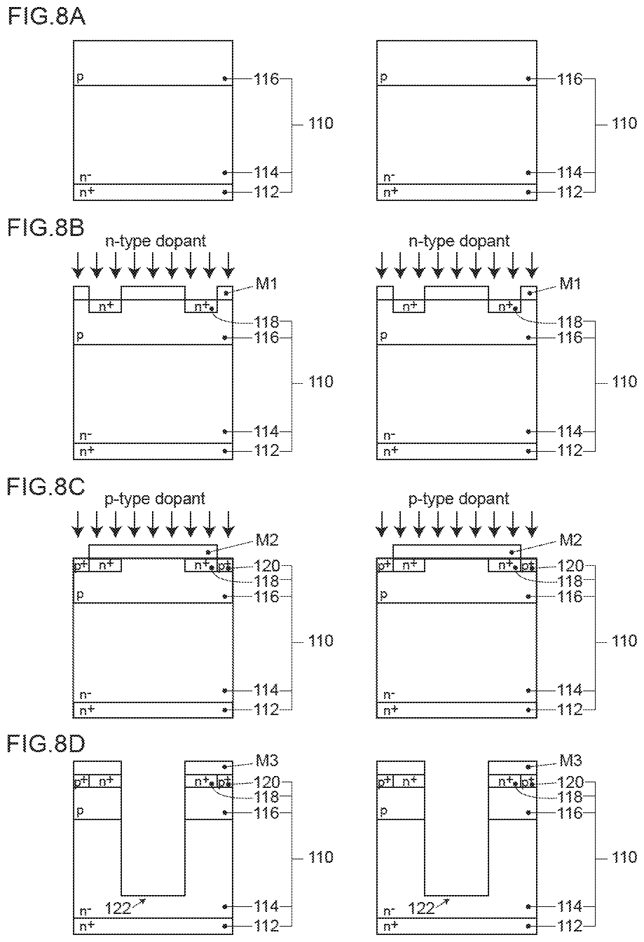

As shown in FIG. 8A to FIG. 8C, there is prepared a semiconductor base body 110 which includes: an n⁺-type drain region 112; an n⁻-type drift region 114 disposed adjacently to the n⁺-type drain region 112; a p-type base region 116 disposed adjacently to the n⁻-type drift region 114; an n⁺-type source region 118 disposed adjacently to the p-type base region 116; and a p⁺-type contact region 120.

### (2) Trench Forming Step

Then, as shown in FIG. 8D, a mask M3 is formed on a surface of the semiconductor base body 110, and a trench 122 is formed using the mask M3 as a mask such that the trench 122 reaches the n⁻-type drift region 114 from a surface of the p-type base region 116. A depth of the trench 122 is set to 12 μm, for example.

### (3) First Electric Insulating Region Forming Step

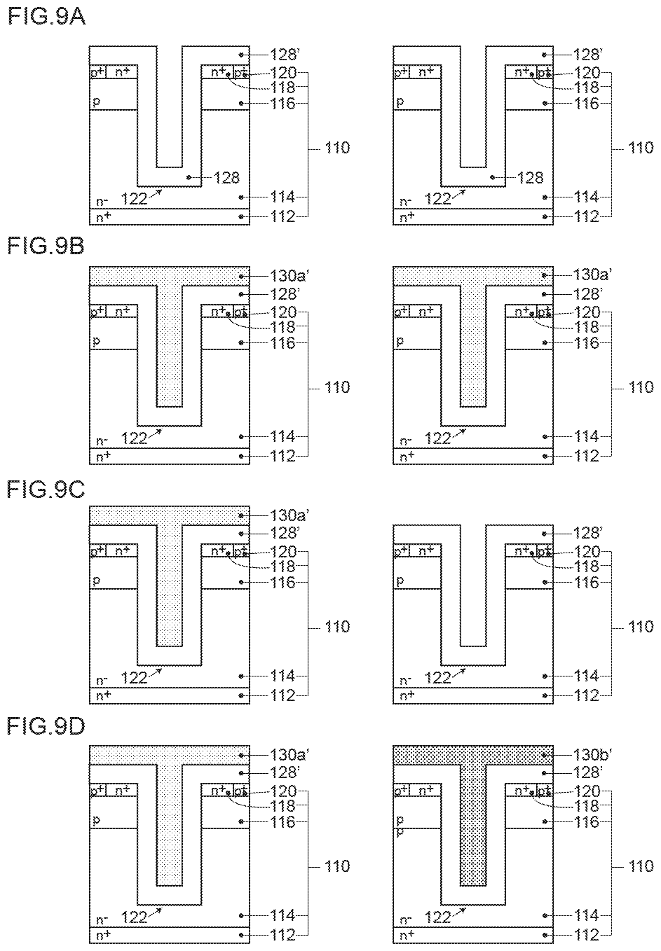

Then, as shown in FIG. 9A, a silicon oxide film 128′ is formed on an inner surface of the trench 122 and a surface of the semiconductor base body 110 by a thermal oxidation method thus forming a bottom portion and a side wall portion of the electric insulating region 128. In the first electric insulating region forming step, the silicon oxide film 128′ on the bottom portion may be formed with a large thickness by a CVD method and, then, the silicon oxide film 128′ on the side wall portion may be formed by a thermal oxidization method.

### (4) Shield Electrode Forming Step

Then, as shown in FIG. 9B, a high resistance polysilicon film 130a′ is formed in the inside of the trench 122 and a surface of the semiconductor base body 110 by a CVD method. Next, as shown in FIG. 9C, the high resistance polysilicon film 130a′ is removed by etching the high resistance polysilicon film 130a′ only in regions where the low resistance region 130b is to be formed. Accordingly, the high resistance polysilicon film 130a′ is formed only in regions where the high resistance region 130a is to be formed in the inside of the trench 122.

Then, as shown in FIG. 9D, a low resistance polysilicon film 130b′ is formed in the inside of the trench 122 and a surface of the semiconductor base body 110 only in regions where the low resistance region 130b is to be formed by a CVD method.

Next, by performing etching back of the high resistance polysilicon film 130a′ and the low resistance polysilicon film 130b′, the high resistance polysilicon film 130a′ and the low resistance polysilicon film 130b′ are removed in a state where the high resistance polysilicon film 130a′ and the low resistance polysilicon film 130b′ having predetermined thicknesses are made to remain.

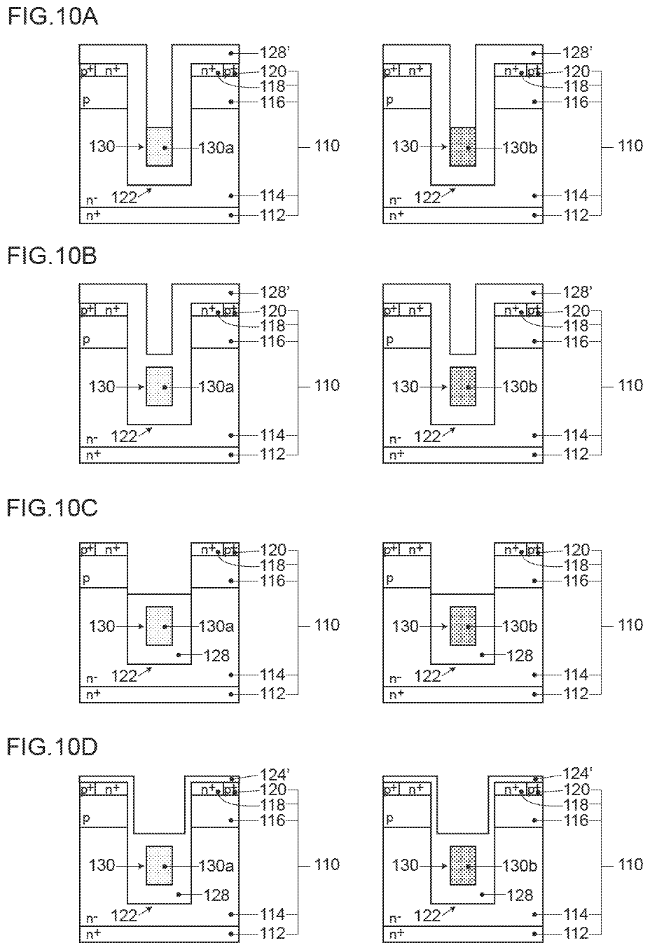

By performing such a step, the high resistance region 130a and the low resistance region 130b are formed in the inside of the trench 122, and as a whole, the shield electrode 130 having the high resistance region 130a and the low resistance region 130b is formed (see FIG. 10A). The shield electrode 130 is formed such that a part of the shield electrode 130 or the whole shield electrode 130 is positioned at a position deeper than a bottom portion of the p-type base region 116.

### (5) Second Electric Insulating Region Forming Step

Then, a silicon oxide film having a predetermined thickness is formed on the high resistance region 130a and the low resistance region 130b in the inside of the trench 122 by a CVD method, and such a silicon oxide film forms a top portion of the electric insulating region 128 (see FIG. 10B)

### (6) Gate Insulating Film Forming Step

Next, as shown in FIG. 10C, the silicon oxide film 128′ formed at a portion where the gate insulating film 124 is to be formed is removed by wet etching. Then, as shown in FIG. 10D, by a thermal oxidation method, a silicon oxide film 124′ is formed on a portion of an inner surface of the trench 122 where the gate insulating film 124 is to be formed and a surface of the semiconductor base body 110, and the silicon oxide film 124′ eventually forms the gate insulating film 124.

### (7) Gate Electrode Forming Step

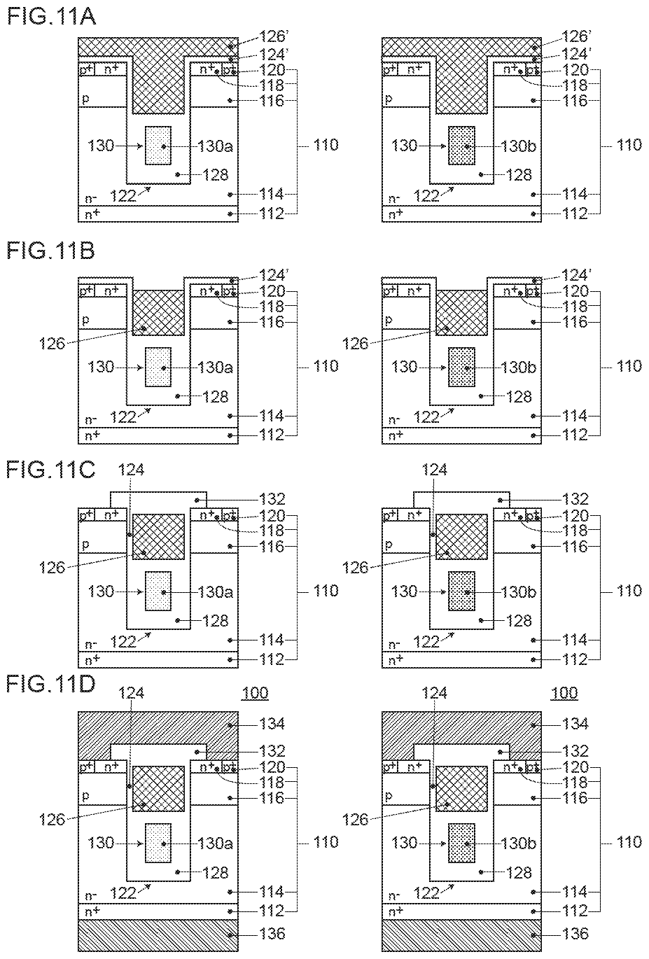

Then, as shown in FIG. 11A, a low resistance polysilicon film 126′ is formed from a surface side of the semiconductor base body 110 such that the trench 122 is embedded by the low resistance polysilicon film 126′. Then, as shown in FIG. 11B, the low resistance polysilicon film 126′ is etched back so as to remove an upper part of the low resistance polysilicon film 126′ in a state where the low resistance polysilicon film 126′ remains only in the trench 122. By performing such a step, the gate electrode 126 is eventually formed on an inner peripheral surface of the trench 122.

### (8) Interlayer Insulating Film Forming Step

Then, the silicon oxide film 124′ formed on the surface of the semiconductor base body 110 is removed. Next, a PSG film is formed from a surface side of the semiconductor base body 110 by a gas phase method. Thereafter, a thermally oxidized film of silicon and the PSG film are removed by etching while a predetermined upper portion of the gate electrode 126 remains. By performing such a step, as shown in FIG. 11C, an interlayer insulating film 132 is formed on an upper portion of the gate electrode 126.

### (9) Source Electrode and Drain Electrode Forming Step

Then, as shown in FIG. 11D, a source electrode 134 is formed such that the source electrode 134 covers the semiconductor base body 110 and the interlayer insulating film 132, and a drain electrode 136 is formed on a surface of the n⁺-type drain region 112.

The semiconductor device 100 according to the embodiment 1 can be manufactured through the above-mentioned steps.

### Embodiment 2

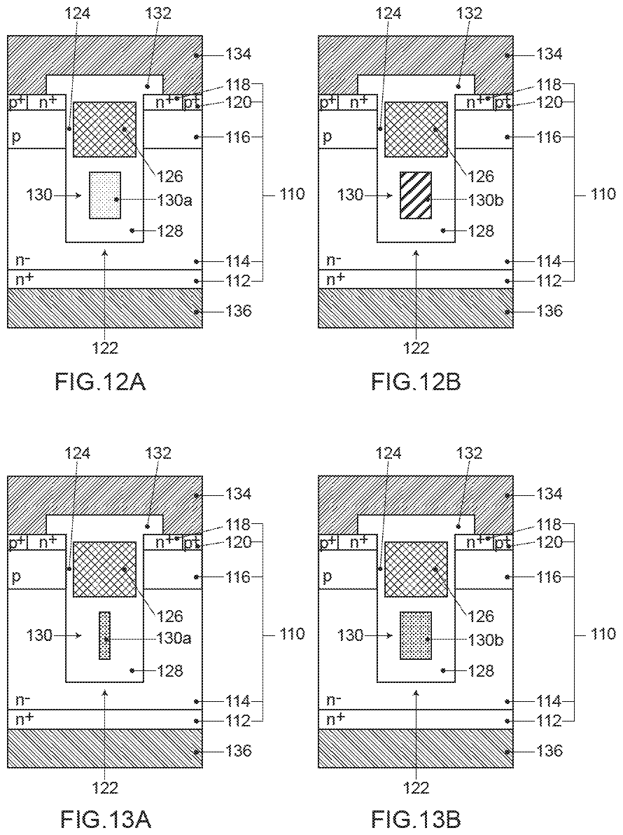

A semiconductor device according to an embodiment 2 basically has substantially the same configuration as the semiconductor device 100 according to the embodiment 1. However, the semiconductor device according to the embodiment 2 differs from the semiconductor device 100 according to the embodiment 1 with respect to the configuration of a shield electrode 130. That is, as shown in FIG. 12, the semiconductor device according to the embodiment 2 includes, as the shield electrode 130, the shield electrode 130 in which high resistance regions 130a and a low resistance region 130b are made of different materials respectively, and electric resistivity of a material which forms the low resistance region 130b is lower than electric resistivity of a material which forms the high resistance region 130a.

As a material for forming the high resistance region 130a, for example, high resistance polysilicon which is formed by a CVD method can be used. As a material for forming the low resistance region 130b, metal having a high-melting point (for example, W, Mo, Ta, Nb or the like) or other metals (for example, Cu or the like) can be used.

In this manner, the semiconductor device according to the embodiment 2 differs from the semiconductor device 100 according to the embodiment 1 with respect to the configuration of the shield electrode 130. However, the semiconductor device according to the embodiment 2 includes, as the shield electrode 130, the shield electrode formed of the high resistance regions 130a positioned at both end portions of the trench 122 as viewed in a plan view and the low resistance region 130b positioned at the position sandwiched by the high resistance regions 130a. Accordingly, in the same manner as the semiconductor device 100 according to the embodiment 1, it is possible to realize the suppression of ringing and a surge voltage, the suppression of an erroneous operation, the prevention of the increase of a switching loss, and the reduction of an adverse effect caused by a surge voltage from the outside.

According to the semiconductor device according to the embodiment 2, by suitably selecting a material for forming the high resistance region 130a and a material for forming the low resistance region 130b, it is possible to select electric resistivity of the high resistance region 130a and electric resistivity of the low resistance region 130b within a wide range.

### Embodiment 3

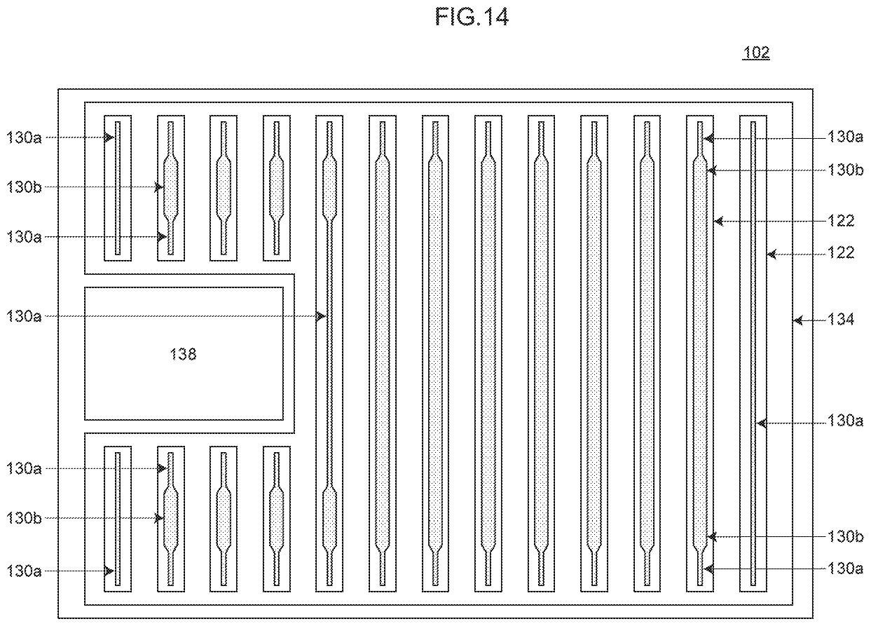

A semiconductor device 102 according to an embodiment 3 basically has substantially the same configuration as the semiconductor device 100 according to the embodiment 1. However, the semiconductor device 102 according to the embodiment 3 differs from the semiconductor device 100 according to the embodiment 1 with respect to the configuration of a shield electrode 130. That is, as shown in FIG. 13 and FIG. 14, the semiconductor device 102 according to the embodiment 3 includes, as the shield electrode 130, the shield electrode 130 where both high resistance regions 130a and a low resistance region 130b are made of the same material, and a cross-sectional area of the high resistance region 130a taken along a plane orthogonal to a longitudinal direction of a trench 122 is smaller than a cross-sectional area of the low resistance region 130b taken along a plane orthogonal to a longitudinal direction of the trench 122.

In this manner, the semiconductor device 102 according to the embodiment 3 differs from the semiconductor device 100 according to the embodiment 1 with respect to the configuration of the shield electrode 130. However, the semiconductor device 102 according to the embodiment 3 includes, as the shield electrode 130, the shield electrode formed of the high resistance regions 130a positioned at both end portions of the trench 122 as viewed in a plan view and the low resistance region 130b positioned at the position sandwiched by the high resistance regions 130a. Accordingly, in the same manner as the semiconductor device 100 according to the embodiment 1, it is possible to realize the suppression of ringing and a surge voltage, the suppression of an erroneous operation, the prevention of the increase of a switching loss, and the reduction of an adverse effect caused by a surge voltage from the outside.

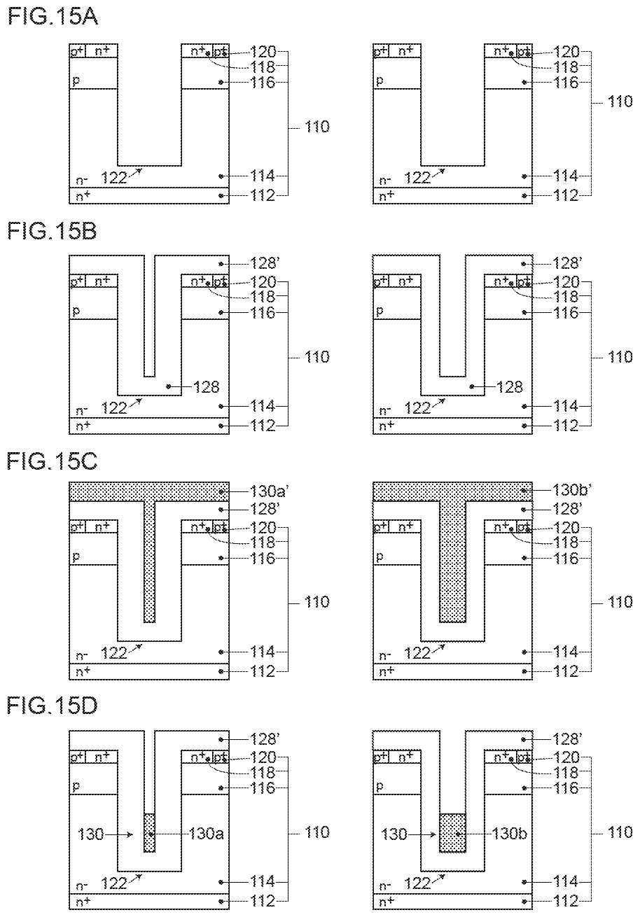

As shown in FIG. 15, the semiconductor device 102 according to the embodiment 3 can be manufactured by a method substantially equal to the method of manufacturing the semiconductor device according to the embodiment 1 except for that a thickness of a side wall portion of an electric insulating region 128 formed in the inside of the trench 122 differs between regions where the high resistance region 130a is formed and a region where the low resistance region 130b is formed (see FIG. 15A and FIG. 15B), and the high resistance regions 130a and the low resistance region 130b are formed without changing the dopant concentration between the high resistance regions 130a and the low resistance region 130b (see FIG. 15C and FIG. 15D).

### Embodiment 4

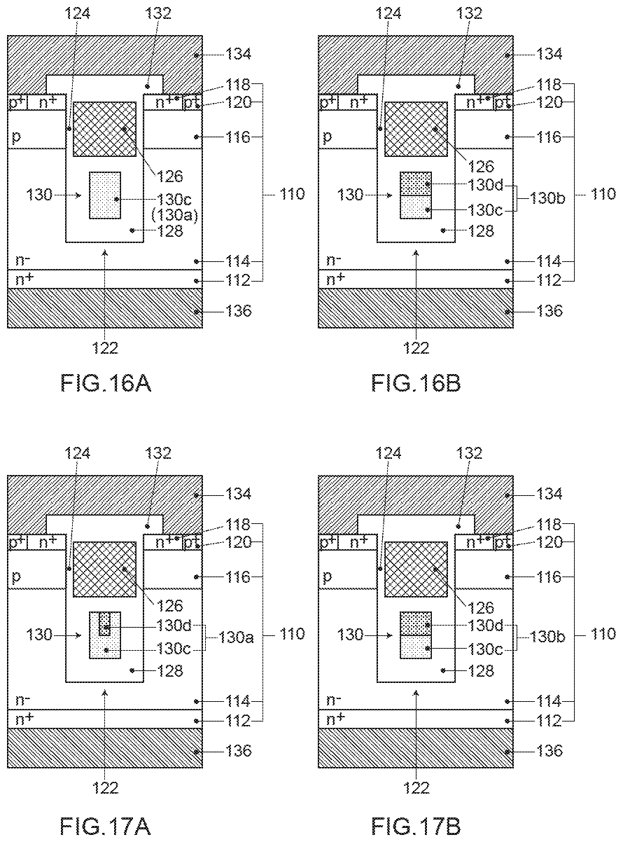

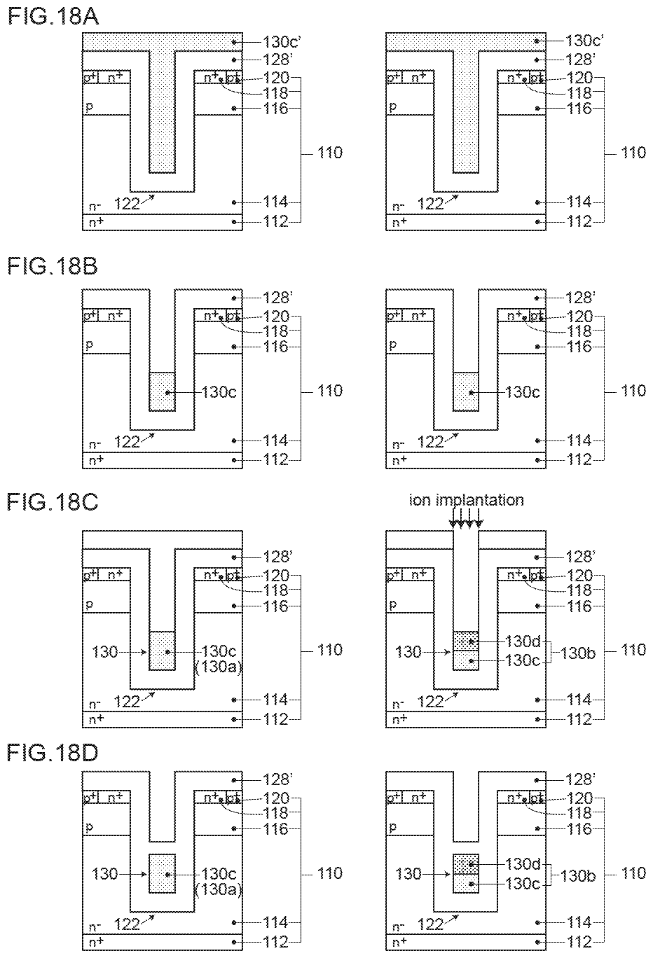

A semiconductor device according to an embodiment 4 basically has substantially the same configuration as the semiconductor device 100 according to the embodiment 1. However, the semiconductor device according to the embodiment 4 differs from the semiconductor device 100 according to the embodiment 1 with respect to the configuration of a shield electrode. That is, as shown in FIG. 16, the semiconductor device according to the embodiment 4 has, as the shield electrode 130, a shield electrode where both high resistance regions and a low resistance region 130b are made of the same semiconductor material containing a dopant, and the low resistance region 130b has a high concentration dopant region 130d containing a dopant having higher concentration than a dopant in the high resistance region 130a and extending along a longitudinal direction of the trench 122. The high resistance regions 130a and the low resistance region 130b can be formed, as shown in FIG. 18 (particularly, FIG. 18C), by forming the high concentration dopant region 130d only in a region where the low resistance region 130b is to be formed in a polysilicon layer 130c at the time of performing ion implantation.

In this manner, the semiconductor device according to the embodiment 4 differs from the semiconductor device 100 according to the embodiment 1 with respect to the configuration of the shield electrode 130. However, the semiconductor device according to the embodiment 4 includes, as the shield electrode 130, the shield electrode formed of the high resistance regions 130a positioned at both end portions of the trench 122 as viewed in a plan view and the low resistance region 130b positioned at the position sandwiched by the high resistance regions 130a. Accordingly, in the same manner as the semiconductor device 100 according to the embodiment 1, it is possible to realize the suppression of ringing and a surge voltage, the suppression of an erroneous operation, the prevention of the increase of a switching loss, and the reduction of an adverse effect caused by a surge voltage from the outside.

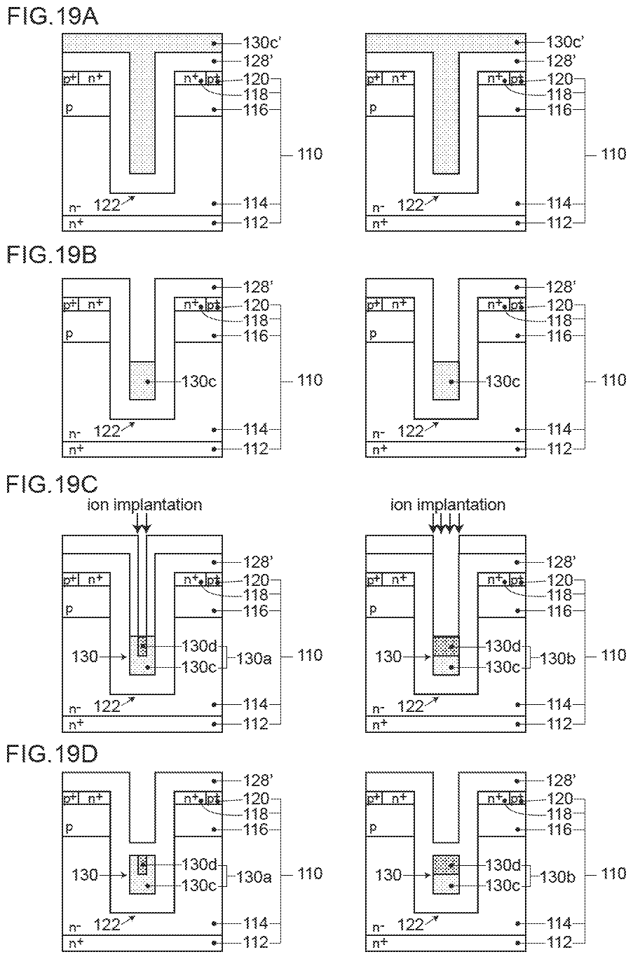

The semiconductor device according to the embodiment 4 can be manufactured by a method substantially equal to the method of manufacturing the semiconductor device according to the embodiment 1 except for steps of forming the high resistance regions 130a and the low resistance region 130b (see FIG. 19).

### Embodiment 5

A semiconductor device according to an embodiment 5 basically has substantially the same configuration as the semiconductor device 100 according to the embodiment 1. However, the semiconductor device according to the embodiment 5 differs from the semiconductor device 100 according to the embodiment 1 with respect to the configuration of a shield electrode 130. That is, as shown in FIG. 17, the semiconductor device according to the embodiment 5 has, as the shield electrode 130, a shield electrode where both high resistance regions 130a and a low resistance region 130b have a high concentration dopant region 130d made of the same semiconductor material containing a dopant, and extending along a longitudinal direction of a trench 122, and a cross-sectional area of the high concentration dopant region 130d in the high resistance region 130a taken along a plane orthogonal to a longitudinal direction of the trench 122 is smaller than a cross-sectional area of the high concentration dopant region 130d in the low resistance region 130b taken along a plane orthogonal to a longitudinal direction of the trench 122. As shown in FIG. 19 (particularly FIG. 19C), the high resistance region 130a and the low resistance region 130b are formed such that a cross-sectional area of the high concentration dopant region 130d is changed by changing an area of the polysilicon layer 130c to which ion implantation is applied between the high resistance region 130a and the low resistance region 130b at the time of performing an ion implantation method.

In this manner, the semiconductor device according to the embodiment 5 differs from the semiconductor device 100 according to the embodiment 1 with respect to the configuration of the shield electrode 130. However, the semiconductor device according to the embodiment 5 includes, as the shield electrode 130, the shield electrode formed of the high resistance regions 130a positioned at both end portions of the trench 122 as viewed in a plan view and the low resistance region 130b positioned at the position sandwiched by the high resistance regions 130a. Accordingly, in the same manner as the semiconductor device 100 according to the embodiment 1, it is possible to realize the suppression of ringing and a surge voltage, the suppression of an erroneous operation, the prevention of the increase of a switching loss, and the reduction of an adverse effect caused by a surge voltage from the outside.

The semiconductor device according to the embodiment 5 can be manufactured by a method substantially equal to the method of manufacturing the semiconductor device according to the embodiment 1 except for steps of forming the high resistance regions 130a and the low resistance region 130b (see FIG. 19).

### Contact Structure in Embodiments 1 to 5

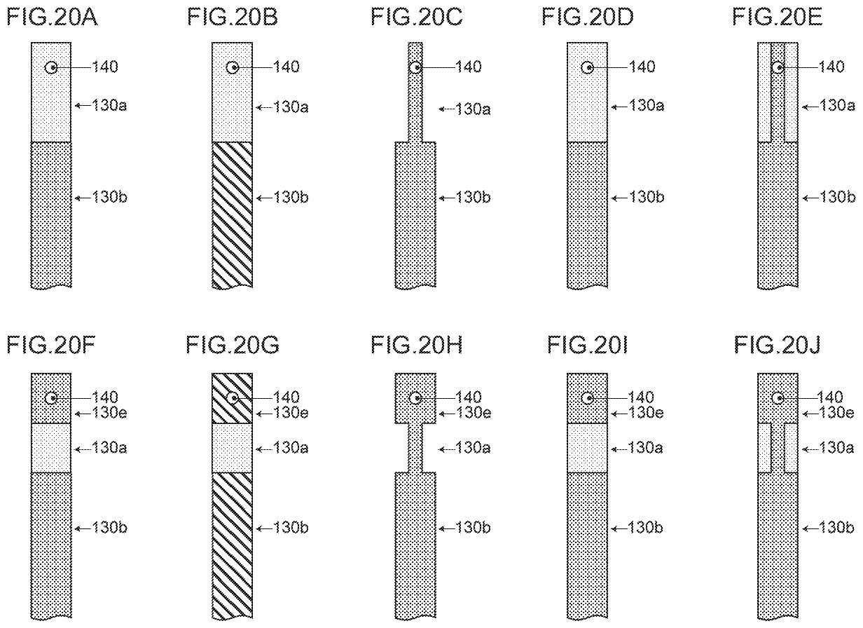

In the semiconductor devices according to the embodiments 1 to 5 of the present invention, as shown in FIG. 20A to FIG. 20E, a contact structure 140 for electrically connecting the shield electrode 130 and the source electrode 134 may be formed on both end portions of the shield electrode 130. In this case, as shown in FIG. 20F to FIG. 20J, the contact structure 140 may be formed in a second low resistance region 130e having a lower resistance than the high resistance region 130a. Also in this case, the high resistance region 130a is positioned in a region sandwiched by the low resistance region 130b and the second low resistance region 130e.

### Embodiment 6

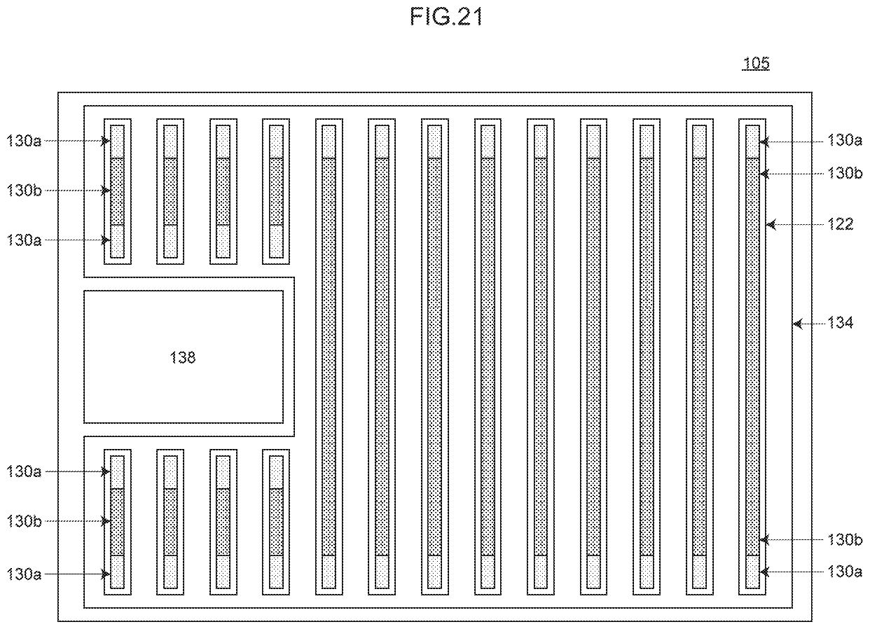

A semiconductor device 105 according to an embodiment 6 basically has substantially the same configuration as the semiconductor device 100 according to the embodiment 1. However, the semiconductor device 105 according to the embodiment 6 differs from the semiconductor device 100 according to the embodiment 1 with respect to the configuration of a shield electrode 130 extending adjacently to a side of a chip as viewed in a plan view. That is, as shown in FIG. 21, in the semiconductor device 105 according to the embodiment 6, the shield electrode 130 extending adjacently to the side of the chip as viewed in a plan view also has, in the same manner as the shield electrodes 130 at other positions, a low resistance region 130b positioned at a position sandwiched by high resistance regions 130a. In the semiconductor device 105 according to the embodiment 6, the shield electrode 130 extending adjacently to a side of a gate pad 138 as viewed in a plan view also has, in the same manner as the shield electrodes 130 at other positions, a low resistance region 130b positioned at a position sandwiched by high resistance regions 130a.

In this manner, the semiconductor device 105 according to the embodiment 6 differs from the semiconductor device 100 according to the embodiment 1 with respect to the configuration of the shield electrode 130 extending adjacently to the side of the chip as viewed in a plan view. However, the semiconductor device 105 according to the embodiment 6 includes, as the shield electrode 130, the shield electrode formed of the high resistance regions 130a positioned at both end portions of the trench 122 as viewed in a plan view and the low resistance region 130b positioned at the position sandwiched by the high resistance regions 130a. Accordingly, in the same manner as the semiconductor device 100 according to the embodiment 1, it is possible to realize the suppression of ringing and a surge voltage, the suppression of an erroneous operation, and the prevention of the increase of a switching loss.

### Embodiment 7

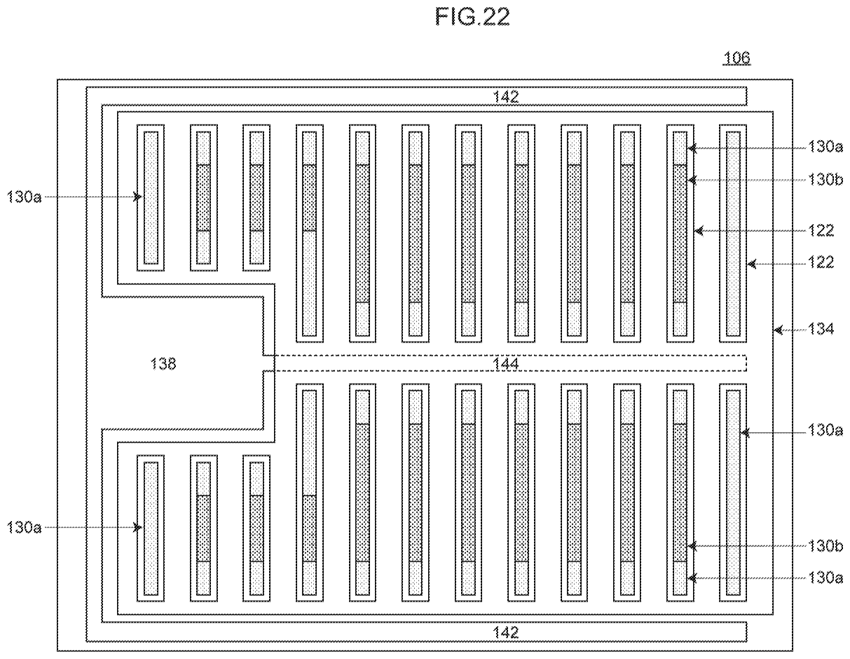

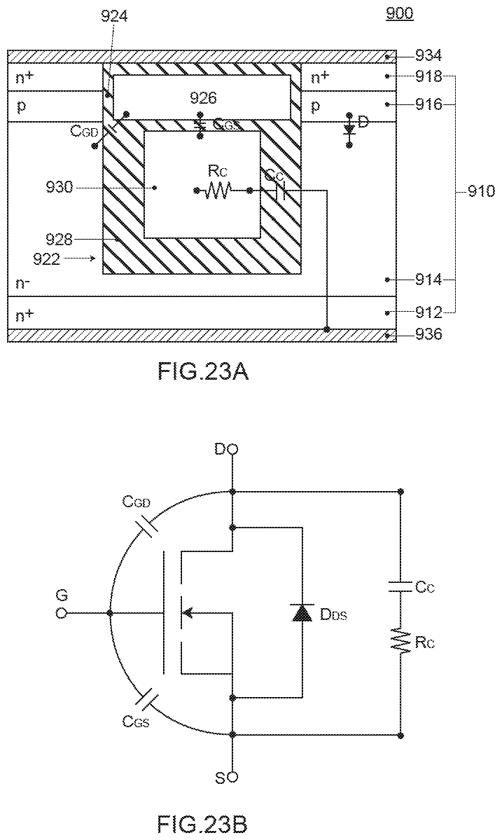

A semiconductor device 106 according to an embodiment 7 basically has substantially the same configuration as the semiconductor device 100 according to the embodiment 1. However, the semiconductor device 106 according to the embodiment 7 differs from the semiconductor device 100 according to the embodiment 1 with respect to the configuration of a gate finger for connecting a gate pad 138 and a gate electrode 126 to each other. That is, although not shown in the drawings, the semiconductor device 100 according to the embodiment 1 includes, as a gate finger, a gate finger 142 extending from a gate pad 138 along an outer peripheral portion of a chip. On the other hand, the semiconductor device 106 according to the embodiment 7 includes, as shown in FIG. 22, as the gate finger, a second gate finger 144 extending from the gate pad 138 in such a manner that the second gate finger 144 penetrates a center portion of the chip in addition to a gate finger 142 extending along an outer peripheral portion of the chip from the gate pad 138. Further, due to such a configuration, a trench 122 is divided by the second gate finger 144.

In this manner, the semiconductor device 106 according to the embodiment 7 differs from the semiconductor device 100 according to the embodiment 1 with respect to the configuration of the gate finger. However, the semiconductor device 106 according to the embodiment 7 includes, as the shield electrode 130, the shield electrode formed of high resistance regions 130a positioned at both end portions of the trench 122 as viewed in a plan view and a low resistance region 130b positioned at a position sandwiched by the high resistance regions 130a. Accordingly, in the same manner as the semiconductor device 100 according to the embodiment 1, it is possible to realize the suppression of ringing and a surge voltage, the suppression of an erroneous operation, the prevention of the increase of a switching loss, and the reduction of an adverse effect caused by a surge voltage from the outside.

Further, the semiconductor device 106 according to the embodiment 7 can also acquire an advantageous effect that an adverse effect caused by a surge voltage from the second gate finger 144 can be reduced.

Although the present invention has been described based on the above-mentioned embodiments heretofore, the present invention is not limited to the above-mentioned embodiments. The present invention can be carried out in various modes without departing from the gist of the present invention, and the following modifications also are conceivable, for example.

(1) In the above-mentioned embodiment 1, for forming the high resistance region 130a, for example, high resistance polysilicon which is formed by a CVD method is used and, for forming the low resistance region 130b, for example, low resistance polysilicon which is formed by a CVD method is used. However, the present invention is not limited to these materials. Materials other than these materials may be used.

(2) In the above-mentioned embodiment 2, for forming the high resistance region 130a, for example, high resistance polysilicon which is formed by a CVD method is used and, for forming the low resistance region 130b, metal having a high-melting point (for example, W, Mo, Ta, Nb or the like) or other metals (for example, Cu or the like) is used. However, the present invention is not limited to these materials. Materials other than these materials may be used.

(3) In the above-mentioned embodiment 1, the description has been made with respect to the case where the semiconductor device 100 is a power MOSFET. However, the present invention is not limited to such a case. The present invention is applicable to various other devices besides the power MOSFET without departing from the gist of the present invention.

(4) The semiconductor device 100 according to the embodiment 1 can be manufactured also by a method different from the method described in the embodiment 1. For example, a shield electrode 130 and a gate electrode 126 are formed and, thereafter, an n⁺-type source region 118 and a p⁺-type contact region 120 may be formed. Further, for example, a shield electrode 130 and a gate electrode 126 are formed and, thereafter, an n⁺-type source region 118, a p-type base region 116 and a p⁺-type contact region 120 may be formed.

(5) In the above-mentioned respective embodiments, the source electrode is electrically connected to the shield electrode on both end portions of the trench as viewed in a plan view, the high resistance regions are positioned at both end portions of the trench as viewed in a plan view, and the low resistance region is positioned at a position sandwiched by the high resistance regions. However, the present invention is not limited to such a configuration. For example, the source electrode may be electrically connected to the shield electrode on one of both end portions of the trench as viewed in a plan view, the high resistance region may be positioned at the end portion of the trench electrically connected to the source electrode out of both end portions of the trench as viewed in a plan view, and the low resistance region may be positioned at a position in front of the high resistance region as viewed from the source electrode.

1. A semiconductor device comprising:
a semiconductor base body having a drain region of a first-conductive-type, a drift region of the first-conductive-type disposed adjacently to the drain region, a base region of a second-conductive-type disposed adjacently to the drift region, and a source region of the first-conductive-type disposed adjacently to the base region;
a trench formed in the inside of the semiconductor base body, having a bottom disposed adjacently to the drift region and a side wall disposed adjacently to the base region and the drift region, and formed into a stripe pattern as viewed in a plan view;
a gate electrode disposed in the inside of the trench and opposedly facing the base region with a gate insulating film interposed therebetween on a portion of the side wall;
a shield electrode disposed in the inside of the trench and positioned between the gate electrode and the bottom of the trench;
an electric insulating region disposed in the inside of the trench, the electric insulating region expanding between the gate electrode and the shield electrode, and further expanding along the side wall and the bottom of the trench so as to separate the shield electrode from the side wall and the bottom;
a source electrode formed above the semiconductor base body, electrically connected to the source region, and electrically connected to the shield electrode on at least one of both end portions of the trench as viewed in a plan view; and
a drain electrode formed adjacently to the drain region, wherein
the shield electrode has a high resistance region positioned at an end portion of the trench which is electrically connected to the source electrode out of both end portions of the trench as viewed in a plan view, and a low resistance region positioned at a position in front of the high resistance region as viewed from the source electrode, and
both the high resistance region and the low resistance region are positioned between the gate electrode and the bottom of the trench.

2. The semiconductor device according to claim 1, wherein both the high resistance region and the low resistance region are made of a same semiconductor material containing a dopant, and dopant concentration in the low resistance region is higher than dopant concentration in the high resistance region.

3. The semiconductor device according to claim 1, wherein the high resistance region and the low resistance region are made of different materials respectively, and electric resistivity of a material for forming the low resistance region is lower than electric resistivity of a material for forming the high resistance region.

4. The semiconductor device according to claim 1, wherein both the high resistance region and the low resistance region are made of a same material, and a cross-sectional area of the high resistance region taken along a plane orthogonal to a longitudinal direction of the trench is smaller than a cross-sectional area of the low resistance region taken along a plane orthogonal to a longitudinal direction of the trench.

5. The semiconductor device according to claim 1, wherein both the high resistance region and the low resistance region are made of a same semiconductor material containing a dopant, and the low resistance region has a high concentration dopant region containing a dopant having higher concentration than a dopant in the high resistance region and extending along a longitudinal direction of the trench.

6. The semiconductor device according to claim 1, wherein both the high resistance region and the low resistance region have a high concentration dopant region made of a same semiconductor material containing a dopant and extending along a longitudinal direction of the trench, and a cross-sectional area of the high concentration dopant region in the high resistance region taken along a plane orthogonal to a longitudinal direction of the trench is smaller than a cross-sectional area of the high concentration dopant region in the low resistance region taken along a plane orthogonal to a longitudinal direction of the trench.

7. The semiconductor device according to claim 1, wherein in the shield electrode, the shield electrode extending adjacently to a side of a chip as viewed in a plan view is wholly formed of the high resistance region.

8. The semiconductor device according to claim 1, wherein in the shield electrode, the shield electrode extending adjacently to a side of a gate pad as viewed in a plan view is configured such that a portion of the shield electrode extending adjacently to the side of the gate pad as viewed in a plan view is formed of the high resistance region.

9. The semiconductor device according to claim 1, wherein in the shield electrode, the shield electrode extending adjacently to a side of a chip as viewed in a plan view is wholly formed of the high resistance region, and in the shield electrode, the shield electrode extending adjacently to a side of a gate pad as viewed in a plan view is configured such that a portion of the shield electrode extending adjacently to the side of the gate pad as viewed in a plan view is formed of the high resistance region.

10. The semiconductor device according to claim 1, wherein a contact structure for electrically connecting the shield electrode and the source electrode is formed on an end portion of the shield electrode connected to the source electrode out of both end portions of the shield electrode.

11. The semiconductor device according to claim 10, wherein the contact structure is formed in a second low resistance region having a lower resistance than the high resistance region.

12. The semiconductor device according to claim 1, wherein the source electrode is electrically connected to the shield electrode on both end portions of the trench as viewed in a plan view, the high resistance region is positioned on both end portions of the trench as viewed in a plan view, and the low resistance region is positioned at a position sandwiched by the high resistance regions.
